(19) United States
(12) Patent Application Publication
(10) Pub. No.: US 2026/0068259 A1
(43) Pub. Date: Mar. 5, 2026

(54) METHOD FOR MANUFACTURING SEMICONDUCTOR DEVICE

(71) Applicant: Samsung Electronics Co., Ltd., Suwon-si (KR)

(72) Inventors: Kang In KIM, Suwon-si (KR); Won A KIM, Suwon-si (KR)

(73) Assignee: Samsung Electronics Co., Ltd., Suwon-si (KR)

(21) Appl. No.: 19/254,567

(22) Filed: Jun. 30, 2025

(30) Foreign Application Priority Data
Aug. 30, 2024 (KR) 10-2024-0117591

(51) Int. Cl. H10D 64/01; H01L 21/308; H01L 21/311

(52) U.S. Cl. CPC H10D 64/027

(57) ABSTRACT

A method for manufacturing the semiconductor device includes providing a substrate which includes a first region, and second and third regions around the first region, the second region being between the first region and the third region; sequentially forming a first mask layer and a first photoresist pattern on the substrate of the first to third regions; etching the first mask layer by using the first photoresist pattern to form a mask pattern; forming a spacer layer along a surface of the mask pattern; forming a second mask layer on the spacer layer; selectively forming a second photoresist pattern on the second mask layer of the second region; and forming a first trench that extending at least partially into the substrate of the first region, and a second trench extending at least partially into the substrate of the third region, by using the second photoresist pattern.

### CROSS-REFERENCE TO RELATED APPLICATION

This application claims priority from Korean Patent Application No. 10-2024-0117591filed on Aug. 30, 2024 in the Korean Intellectual Property Office, and all the benefits accruing therefrom under 35 U.S.C. 119, the contents of which in its entirety are herein incorporated by reference.

### BACKGROUND

Some example embodiments relate to a method for manufacturing a semiconductor device. Specifically, some example embodiments relate to a method for manufacturing a semiconductor device which includes a buried channel array transistor (BCAT) or a buried channel access transistor in the form in which a plurality of word lines are buried in a substrate.

As semiconductor elements become more highly integrated, individual circuit patterns are becoming finer, so as to implement more semiconductor elements in the same area. For example, as an integration degree of semiconductor elements increases, design rules of the components of the semiconductor elements are decreasing.

On the other hand, in highly scaled semiconductor elements, the process of forming the plurality of gate electrodes and contacts connected to the plurality of gate electrodes becomes increasingly complex and difficult.

### SUMMARY

Some example embodiments may provide a method for manufacturing a semiconductor device having improved reliability.

However, aspects of example embodiments are not restricted to the one set forth herein. The above and other aspects of example embodiments may will become more apparent to one of ordinary skill in the art to which inventive concepts by referencing the detailed description of some example embodiments given below.

According to some example embodiments, a method for manufacturing a semiconductor device including a first region, and second and third regions around the first region, the second region being between the first region and the third region is provided. The method includes sequentially forming a first mask layer and a first photoresist pattern on the substrate of the first to third regions; etching the first mask layer by using the first photoresist pattern to form a mask pattern; forming a spacer layer along a surface of the mask pattern; forming a second mask layer on the spacer layer; selectively forming a second photoresist pattern on the second mask layer of the second region; and forming a first trench extending at least partially into the substrate of the first region and a second trench extending at least partially into the substrate of the third region, the forming the first and second trench patterns by the use of the second photoresist pattern.

Alternatively or additionally, a method of manufacturing a semiconductor device according to some example embodiments includes providing a substrate includes an element region, and first and second scribe regions around the element region, the first scribe region arranged between the element region and the second scribe region; sequentially forming a first mask layer and a first photoresist pattern on the substrate of the element region, the first scribe region, and the second scribe region; etching the first mask layer by using the first photoresist pattern to form a mask pattern in the element region, the first scribe region, and the second scribe region; forming a spacer layer along a surface of the mask pattern; forming a second mask layer on the spacer layer; selectively forming a second photoresist pattern on the second mask layer of the first scribe region; forming a first alignment key by using the first photoresist pattern of the first scribe region; forming a dummy key by using the first photoresist pattern of the second scribe region; and forming a second alignment key by the use of the second photoresist pattern.

Alternatively or additionally according to some example embodiments, a method for manufacturing a semiconductor device includes providing a substrate including an element region and first and second scribe regions around the element region, the first scribe region between the element region and the second scribe region; sequentially forming a first oxide layer, a second oxide layer, and a first mask layer on the element region, the first scribe region, and the second scribe region; sequentially forming a second mask layer and a first photoresist pattern on the first mask layer; etching the second mask layer by using the first photoresist pattern to form a mask pattern; forming a spacer layer along an upper face of the first mask layer and a surface of the mask pattern; forming a third mask layer on the spacer layer; selectively forming a second photoresist pattern on the third mask layer of the first scribe region; etching the second mask layer of the element region and the second scribe region by the use of the second photoresist pattern to expose an upper face of the spacer layer of the element region and the second scribe region and an upper face of the mask pattern; and forming a first trench that at least partially extends into the substrate in the element region, and a second trench least partially extending into the substrate in the second scribe region, by utilizing etching selectivity of the spacer layer and the mask pattern, in which a width of the first trench is same as a width of the second trench, and a depth of the first trench is same as a depth of the second trench.

Specific details of the method for manufacturing a semiconductor device according to some example embodiments and other example embodiments for achieving the above technical object are included in the description and drawings of inventive concepts.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic plan view showing a configuration before a semiconductor device according to some example embodiments is cut into chips;

FIG. 2 is an enlarged view of a region P of FIG. 1;

FIG. 3 is a plan view for explaining an alignment key and a dummy key according to some example embodiments;

FIG. 4 is a schematic layout diagram of a region R1 of FIG. 2;

FIG. 5 is a schematic layout diagram of a region R2 of FIG. 2;

FIG. 6 is a schematic layout diagram of a region R3 of FIG. 2;

FIGS. 7 to 20 are diagrams for explaining a method for manufacturing a semiconductor device according to some example embodiments; and

FIG. 21 is a schematic layout diagram of the region R3 according to some example embodiments, corresponding to FIG. 6.

### DETAILED DESCRIPTION OF SOME EXAMPLE EMBODIMENTS

Some example embodiments will be described below with reference to the attached drawings.

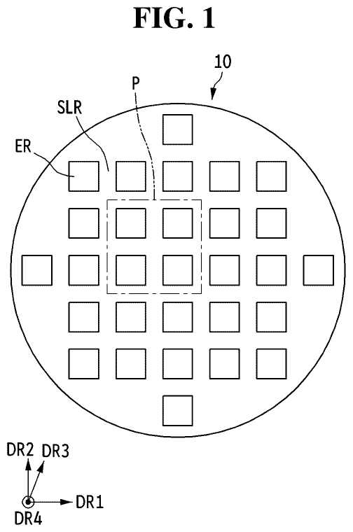

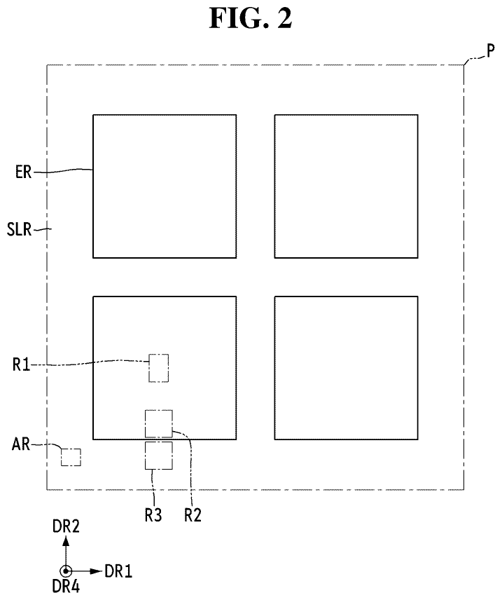

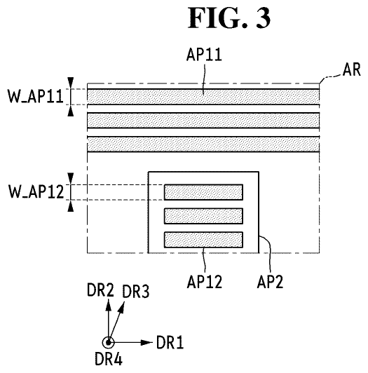

FIG. 1 is a schematic plan view showing a configuration before a semiconductor device according to some example embodiments is cut into chips. FIG. 2 is an enlarged view of a region P of FIG. 1. FIG. 3 is a plan view for explaining an alignment key and a dummy key according to some example embodiments.

Referring to FIGS. 1 and 2, a semiconductor device 10 according to some example embodiments may include at least one element region ER, and a kerf region or scribe region SLR that surrounds the element region ER before being cut into chips. The scribe region SLR may be disposed around the element region ER. The element region ER may be arranged in a lattice shape with the scribe region SLR sandwiched therebetween.

The semiconductor device 10 may be or may include a wafer, such as but not limited to a silicon wafer. The semiconductor device 10 may be circular, and may have a diameter of 200 mm, or 300 mm, or 450 mm; example embodiments are not limited thereto. In some example embodiments, the semiconductor device 10 may have a notch and/or a flat on an edge thereof; example embodiments are not limited thereto.

Although not specifically shown, the semiconductor device 10 according to some example embodiments may include a plurality of shot regions (not shown) including at least one element region ER. In some example embodiments, the shot region may correspond to a photolithographic region, and may include one or a plurality of element regions ER arranged in a rectangular, e.g., square, fashion. After being cut or diced into chips, the semiconductor device 10 may have substantially the same size as the shot region (not shown). When the semiconductor device 10 is cut into chips, the scribe region SLR may be partially and/or entirely lost due to dicing.

In some example embodiments, a key region AR may be disposed in the scribe region SLR. The key region AR may be disposed on one side and/or the other side of the scribe region SLR. For example, the key region AR may be disposed in an edge region of the scribe region SLR. However, the position of the key region AR is not limited to that shown in the drawings.

A first alignment key AP11, a dummy key AP12, and a second alignment key AP2 may be formed in the key region AR. From a planar view point, a width W_AP12 of the dummy key AP12 may be smaller than a width of the second alignment key AP2. The width W_AP12 of the dummy key AP12 may be the same as the width W_AP11 of the first alignment key AP11. An interval or spacing between the dummy keys AP12 may be the same as an interval or spacing between the first alignment keys AP11.

In some example embodiments, a misalignment may be measured, using the first and second alignment keys AP11 and AP2 formed in the key region AR. Alternatively or additionally, by improving the steps, e.g., sharp steps, between the patterns formed in the element region ER and the scribe region SLR in a subsequent process by using the dummy key AP12, a semiconductor device with improved reliability may be manufactured.

The contents associated with the formation of the first and second alignment keys AP11 and AP2, and the dummy key AP12 will be described below.

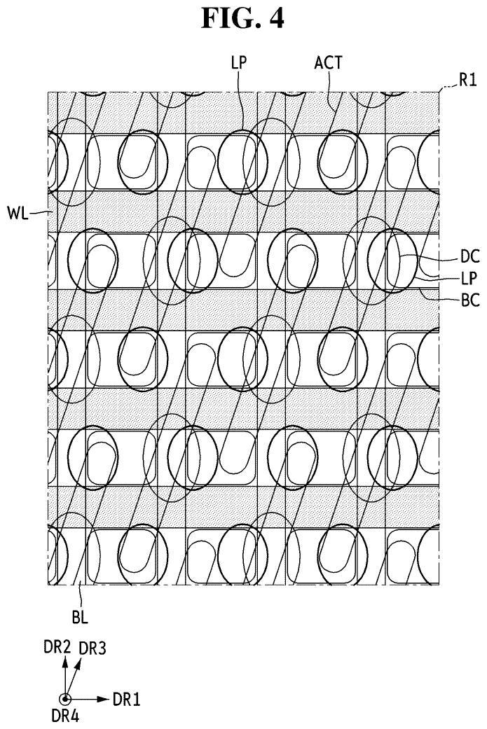

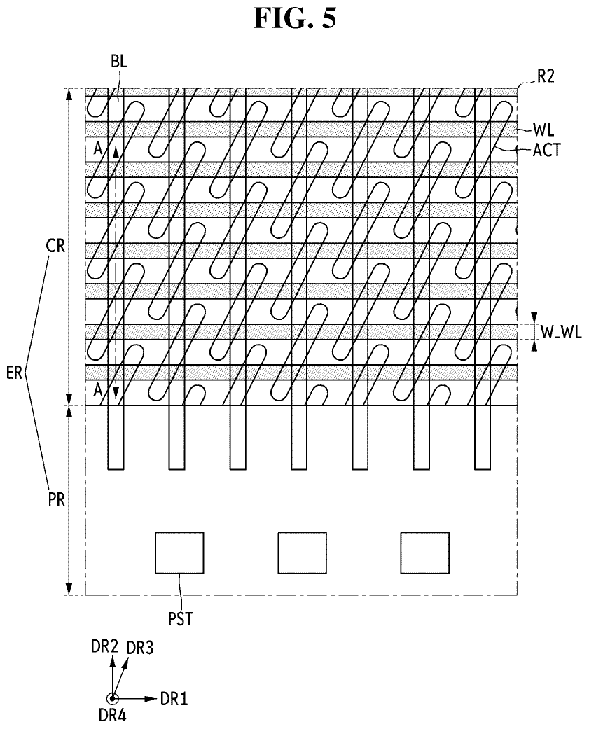

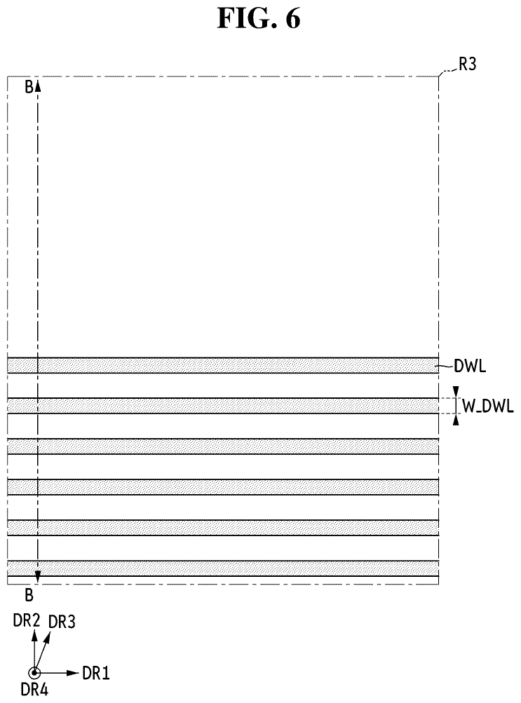

FIG. 4 is a schematic layout diagram of the region R1 of FIG. 2. FIG. 5 is a schematic layout diagram of the region R2 of FIG. 2. FIG. 6 is a schematic layout diagram of the region R3 of FIG. 2.

In the diagrams of the semiconductor device according to some example embodiments, a dynamic random access memory (DRAM) is shown as an example, but is not limited thereto.

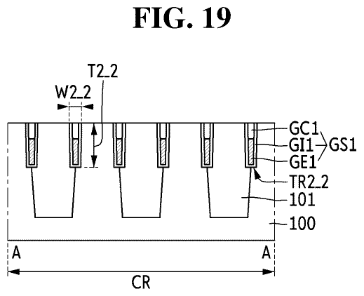

The element region ER may include a plurality of cell active regions ACT. The cell active regions ACT may be defined by a cell element isolation film (101 of FIG. 19) formed inside a substrate (100 of FIG. 19). With a decrease in the design rule of the semiconductor device, the cell active regions ACT may be disposed in the form of a bar of a diagonal line or an oblique line, as shown. For example, the cell active regions ACT may extend in a third direction DR3. An angle between the third direction DR3 and the first direction DR2 may be greater than or equal to 45 degrees; example embodiments are not limited thereto.

A plurality of gate electrodes extending in the first direction DR1 across the cell active regions ACT may be disposed. The plurality of gate electrodes may extend to be parallel to each other. The plurality of gate electrodes may be or may correspond to, for example, a plurality of word lines WL. The word lines WL may be disposed at equal intervals, e.g., at a constant pitch. The width of the word line WL or the interval between the word lines WL may be determined depending on a design rule.

Each cell active region ACT may be divided into three portions by two word lines WL extending in the first direction DR1. The cell active region ACT may include a storage connecting region and a bit line connecting region. The bit line connecting region may be located in a central portion of the cell active region ACT, and the storage connecting region may be located at an end of the cell active region ACT.

A plurality of bit lines BL extending in the second direction DR2 perpendicular to the word lines WL may be disposed on the word lines WL. The plurality of bit lines BL may extend to be parallel to each other. The bit lines BL may be disposed at equal intervals, e.g., at a constant pitch. The width of the bit lines BL or the interval between the bit lines BL may be determined depending on a design rule.

A fourth direction DR4 may be perpendicular to the first direction DR1, the second direction DR2, and the third direction DR3. The fourth direction DR4 may be a thickness direction of the substrate (100 of FIG. 19).

The semiconductor device according to some example embodiments may include various contact arrangements formed on the cell active region ACT. The various contact arrangements may include, for example, a direct contact or digit contact DC, a buried contact BC, a landing pad LP, and the like.

Here, the digit contact DC may refer to a contact that electrically connects the cell active region ACT to the bit line BL. The buried contact BC may refer to a contact that connects the cell active region ACT to a capacitor electrode (not shown). The contact area between the buried contact BC and the cell active region ACT may be small due to the placement structure. Therefore, a conductive landing pad LP may be introduced to expand the contact area with the cell active region ACT and the contact area with the capacitor electrode (not shown).

The landing pad LP may be disposed between the cell active region ACT and the buried contact BC, or may be disposed between the buried contact BC and a capacitor electrode (not shown). In the semiconductor device according to some example embodiments, the landing pad LP may be disposed between the buried contact BC and a capacitor electrode (not shown). By expanding the contact area through the introduction of the landing pad LP, the contact resistance between the cell active region ACT and the capacitor electrode (not shown) may decrease.

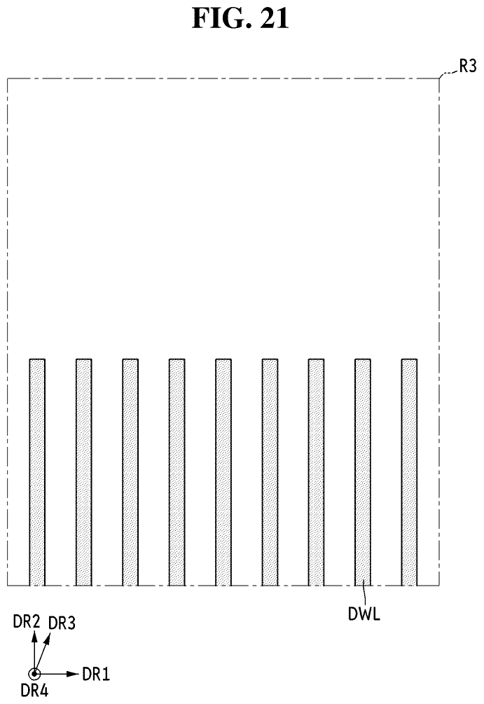

The digit contact DC may be connected to the bit line connecting region. The buried contact BC may be connected to the storage connecting region. As the buried contact BC is disposed at both end portions of the cell active region ACT, the landing pad LP may be disposed to be adjacent to both ends of the cell active region ACT to partially overlap the buried contact BC. For example, the buried contact BC may be formed to overlap the cell active region ACT and the cell element isolation film (101 of FIG. 21) between the adjacent word line WL and between the adjacent bit lines BL.

The word line WL may be formed in a structure buried inside the substrate (100 of FIG. 19). The word line WL may be disposed across the cell active region ACT between the direct contact DC and the buried contact BC. As shown, two word lines WL may be disposed to cross one cell active region ACT. Because the cell active region ACT extends along the third direction DR3, the word line WL may have an angle of less than 90 degrees with the cell active region ACT.

The digit contact DC and the buried contact BC may be disposed symmetrically. Thus, the digit contact DC and the buried contact BC may be disposed on a straight line along the first direction DR1 and the second direction DR2. Meanwhile, unlike the digit contact DC and the buried contact BC, the landing pads LP may be disposed in zigzags in the second direction DR2 in which the bit line BL extends. The landing pads LP may also be disposed to overlap the same side face portions of each bit line BL in the first direction DR1 in which the word line WL extends. For example, each of the landing pads LP of the first line may overlap the left side face of the corresponding bit line BL, and each of the landing pads LP of the second line may overlap the right side face of the corresponding bit line BL.

In some example embodiments, the element region ER may include a cell region CR and a peripheral region PR. The cell region CR may be or may include a region in which a plurality of cell active regions ACT are disposed. The peripheral region PR may be disposed around the cell region CR. The peripheral region PR may be disposed between the cell region CR and the scribe region SLR. At least one peripheral element PST may be disposed in the peripheral region PR. However, the position and number of the peripheral element PST are not limited to those shown in the drawing.

The dummy word line DWL may extend in a direction parallel to the word line WL from a planar view point. The dummy word line DWL may not be electrically active during operation of the semiconductor device. A width W_DWL of the dummy word line DWL may be the same as a width W_WL of the word line WL. An interval between the dummy word lines DWL may be the same as an interval between the word lines WL.

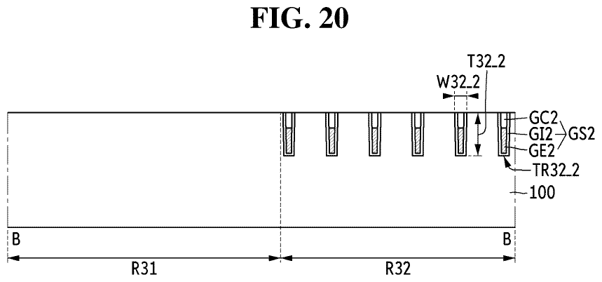

Accordingly, the direction DR1 in which the trench (TR32_2 of FIG. 20) with the dummy word line DWL formed thereon extends may be parallel to the direction DR1 in which the trench (TR2_2 of FIG. 19) with the word line WL formed thereon extends. However, the technical idea of example embodiments is not limited thereto, and as described below, the dummy word line DWL may extend in a direction different from that of the word line WL.

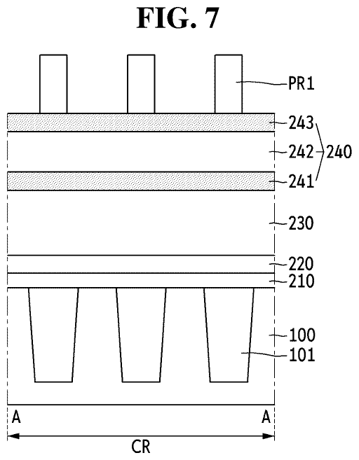

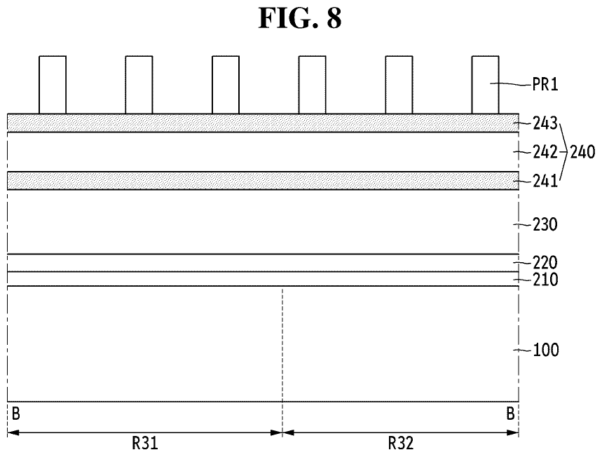

FIGS. 7 to 20 are diagrams for explaining a method for manufacturing a semiconductor device according to some example embodiments. For reference, FIGS. 7, 9, 11, 13, 15, 17, and 19 are diagrams corresponding to the cross-sectional view taken along line A-A of FIG. 5. FIGS. 8, 10, 12, 14, 16, 18, and 20 are diagrams corresponding to the cross-sectional view taken along line B-B of FIG. 6.

Referring to FIGS. 7 and 8, a substrate 100 that includes a cell region CR, and first and second scribe regions R31 and R32 disposed around the cell region CR is provided. The first scribe region R31 may be disposed between the cell region CR and the second scribe region R32.

The substrate 100 may include, for example, a semiconductor substrate such as one or more of a silicon substrate, a germanium substrate or a silicon-germanium substrate. The substrate 100 may include one or more of a silicon-on-insulator (SOI) substrate, a germanium-on-insulator (GOI) substrate, or the like. In some example embodiments, the substrate 100 may include impurities. For example, the substrate 100 may include n-type impurities (e.g., one or more of phosphorus (P), arsenic (As), etc.).

A cell element isolation film 101 may be formed inside the substrate 100 of the cell region CR. The cell element isolation film 101 may have a shallow trench isolation (STI) structure having good or excellent element isolation characteristics. The cell element isolation film 101 may define a cell active region ACT inside the cell region CR. The cell active region ACT defined by the cell element isolation film 101 may have a long island formation including a short axis and a long axis, as shown in FIG. 4. The cell active region ACT may have an oblique line form to have an angle of less than 90 degrees with respect to the word line WL formed in the cell element isolation film 101. The cell active region ACT may also have an oblique line form to have an angle of less than 90 degrees with respect to the bit line BL formed on the cell element isolation film 101. In some example embodiments, the cell element isolation film 101 may be formed with a process such as a shallow trench isolation (STI) process and/or a spin-on dielectric (SOD) process such as a spin-on glass (SOG) process; example embodiments are not limited thereto.

The cell element isolation film 101 may include, but not limited to, at least one of a silicon oxide film, a silicon nitride film, and a silicon oxynitride film. The cell element isolation film 101 may be formed of one insulating film or may be formed of a plurality of insulating films, depending on the width of the cell element isolation film 101.

A first oxide layer 210, a second oxide layer 220, and a first mask layer 230 may be sequentially formed on the cell region CR, the first scribe region R31, and the second scribe region R32. The oxide layer 210, the second oxide layer 220, and the first mask layer 230 may be sequentially formed with a process such as one or more of a chemical vapor deposition process or an atomic layer deposition process; example embodiments are not limited thereto.

For example, the first and second oxide layers 210 and 220 may include, but not limited to, an oxide such as silicon oxide.

For example, the first mask layer 230 may include a carbon-based material. For example, the first mask layer 230 may include, but not limited to, a spin-on hard mask (SOH).

Next, a second mask structure 240 may be formed on the first mask layer 230 of the cell region CR, the first scribe region R31, and the second scribe region R32.

The second mask structure 240 may include a first etching stop layer 241, a third mask layer 242, and a second etching stop layer 243, which are sequentially stacked.

For example, the first etching stop layer 241 and the second etching stop layer 243 may include, but not limited to, a nitride. For example, the first etching stop layer 241 and the second etching stop layer 243 may include, but not limited to, SiON.

For example, the third mask layer 242 may include, but not limited to, a carbon-based material. For example, the third mask layer 242 may include, but not limited to, a spin-on hard mask (SOH).

After that, a first photoresist pattern PR1 may be formed on the second mask structure 240 of the cell region CR, the first scribe region R31, and the second scribe region R32. The first photoresist patterns PR1 may be formed in each of the cell region CR, the first scribe region R31, and the second scribe region R32 to be spaced apart from each other at a predetermined interval.

For example, the first photoresist pattern PR1 may include, but not limited to, a photosensitive material such as an organic photosensitive material.

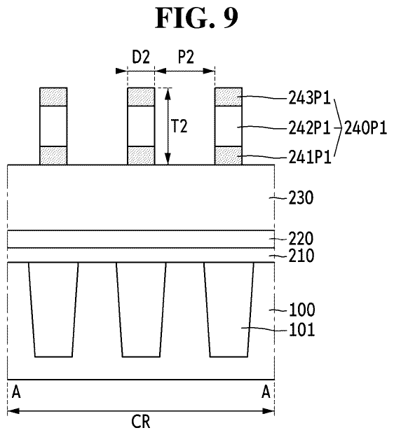

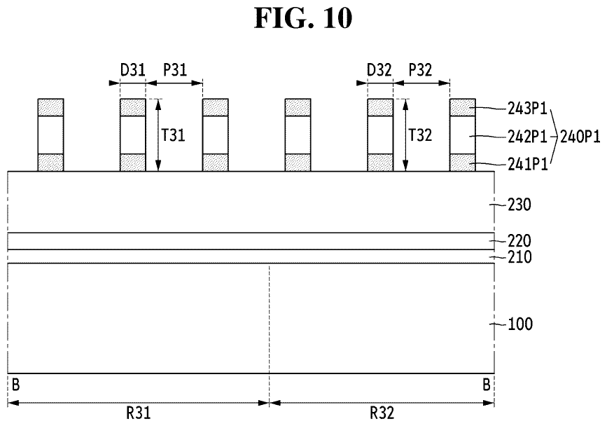

After that, referring to FIGS. 9 and 10, a mask pattern 240P1 may be formed in the cell region CR, the first scribe region R31, and the second scribe region R32. The mask pattern 240P1 may be formed by etching the second mask structure 240 by the use of the first photoresist pattern (PR1 of FIGS. 7 and 8). Accordingly, a part of the upper face of the first mask layer 230 and the side face and the upper face of the mask pattern 240P1 may be exposed. The cell region CR, the first scribe region R31, and the second scribe region R32 may be formed with an etching process such as but not limited to a dry etching process and/or a wet etching process; example embodiments are not limited thereto.

The mask pattern 240P1 may include a first etching stop layer pattern 241P1, a third mask layer pattern 242P1, and a second etching stop layer pattern 243P1. Specifically, the side face of the first etching stop layer pattern 241P1, the side face of the third mask layer pattern 242P1, the side face of the second etching stop layer pattern 243P1, and the upper face of the second etching stop layer pattern 243P1 may be exposed.

A spacing or an interval P2 between the mask patterns 240P1 of the cell region CR, a spacing or an interval P31 between the mask patterns 240P1 of the first scribe region R31, and a spacing or an interval P32 between the mask patterns 240P1 of the second scribe region R32 may be the same as each other.

A width D2 of the mask pattern 240P1 of the cell region CR, a width D31 of the mask pattern 240P1 of the first scribe region R31, and a width D32 of the mask pattern 240P1 of the second scribe region R32 may be the same as each other.

A thickness T2 of the mask pattern 240P1 of the cell region CR, a thickness T31 of the mask pattern 240P1 of the first scribe region R31, and a thickness T32 of the mask pattern 240P1 of the second scribe region R32 may be the same as each other.

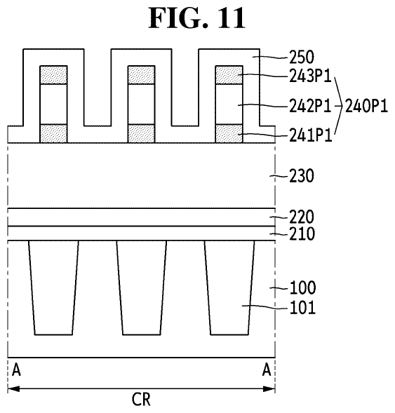

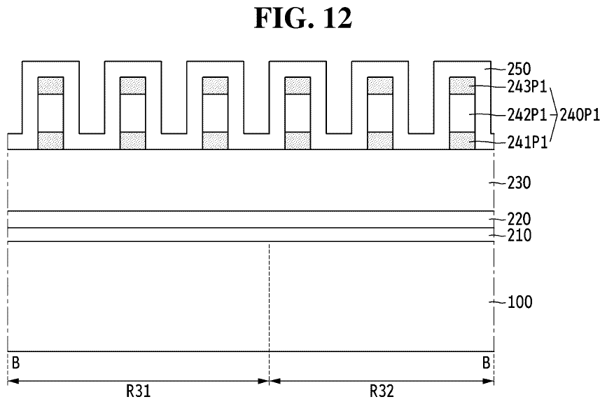

Next, referring to FIGS. 11 and 12, a spacer layer 250 may be formed on the first mask layer 230 of the cell region CR, the first scribe region R31, and the second scribe region R32. The spacer layer 250 may be conformally formed along the upper face of the first mask layer 230 and the side and upper faces of the mask pattern 240P1.

Specifically, the spacer layer 250 may be conformally formed along the upper face of the first mask layer 230, the side face of the first etching stop layer pattern 241P1, the side face of the third mask layer pattern 242P1, the side face of the second etching stop layer pattern 243P1, and the upper face of the second etching stop layer pattern 243P1 in the cell region CR, the first scribe region R31, and the second scribe region R32.

For example, the spacer layer 250 may include an oxide. For example, the spacer layer 250 may be formed by an atomic layer deposition (ALD) process.

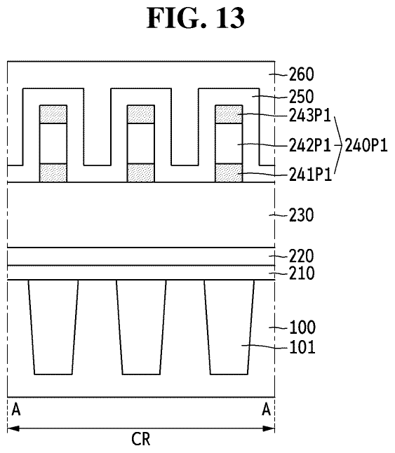

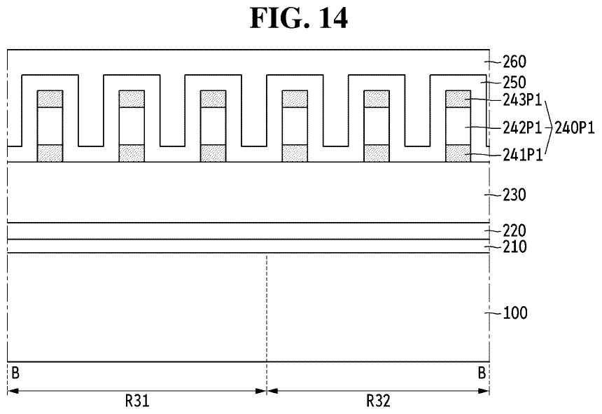

Subsequently, referring to FIGS. 13 and 14, a fourth mask layer 260 may be formed on the spacer layer 250 of the cell region CR, the first scribe region R31, and the second scribe region R32.

A fourth mask layer 260 may fill the space between the spacer layer 250 on the spacer layer 250. The fourth mask layer 260 may be formed to cover the spacer layer 250.

For example, the fourth mask layer 260 may include a carbon-based material. For example, the fourth mask layer 260 may include, but not limited to, a spin-on hard mask (SOH).

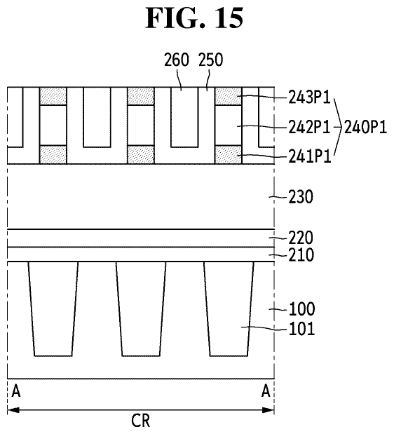

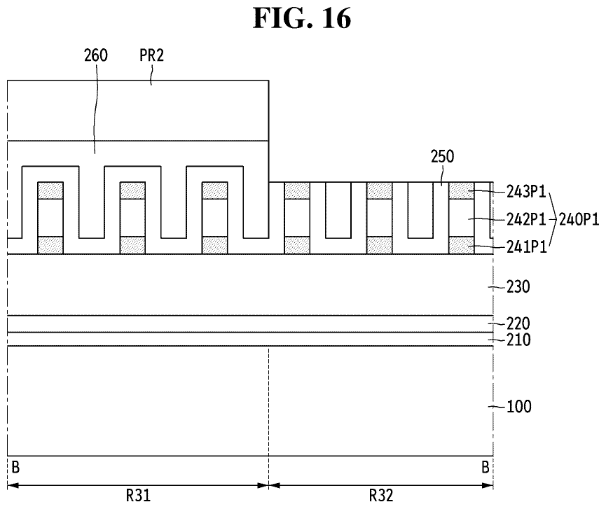

Next, referring to FIGS. 15 and 16, a second photoresist pattern PR2 may be selectively formed on the third mask layer 260 of the first scribe region R31. In this case, the second photoresist pattern PR2 may not be formed on the third mask layer 260 of the cell region CR and the second scribe region R32.

Next, the second mask layer 260 of the cell region CR and the second scribe region R32 may be etched using the second photoresist pattern PR2, thereby exposing the upper face of the spacer layer 250 and the upper face of the mask pattern 240P1 of the cell region CR and the second scribe region R32.

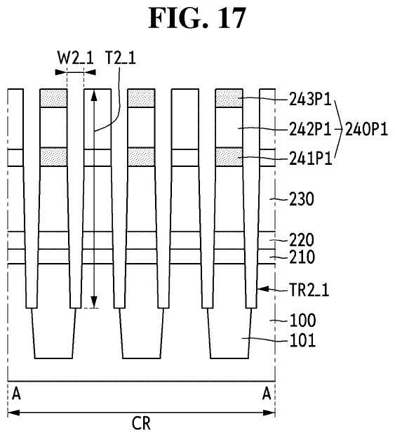

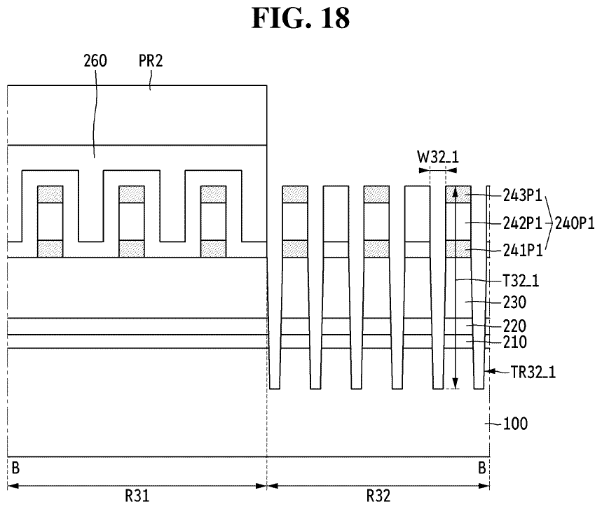

Next, referring to FIGS. 17 and 18, a first trench TR2_1 which penetrates the spacer layer 250, the first mask layer 230, the second oxide layer 220, and the first oxide layer 210 and extends at least partially into the substrate 100 may be formed in the cell region CR.

In addition, a second trench TR32_1 which penetrates the spacer layer 250, the first mask layer 230, the second oxide layer 220, and the first oxide layer 210 and at least partially extends into the substrate 100 may be formed in the second scribe region R32.

The first trench TR2_1 and the second trench TR32_1 may be formed, using the etching selectivity of the spacer layer 250 and the mask pattern 240P1. The first trench TR2_1 and the second trench TR32_1 may be formed simultaneously in the same process.

A width W2_1 of the first trench TR2_1 may be the same as a width W32_1 of the second trench TR32_1. A depth T2_1 of the first trench TR2_1 may be the same as a depth T32_1 of the second trench TR32_1.

The first alignment key (AP11 of FIG. 3) may be formed using the first photoresist pattern (PR1 of FIGS. 7 and 8) of the first scribe region R31. The dummy key (AP12 of FIG. 3) may be formed using the first photoresist pattern (PR1 of FIGS. 7 and 8) of the second scribe region R32. The second alignment key AP2 may be formed using the second photoresist pattern (PR2 of FIGS. 16 and 18).

Next, referring to FIGS. 19 and 20, the spacer layer 250, the mask pattern 240P1, the first mask layer 230, the second oxide layer 220 and the first oxide layer 210 of the cell region CR, the first scribe region R31 and the second scribe region R32 may be removed. The fourth mask layer 260 and the second photoresist pattern PR2 of the first scribe region R31 may be removed.

A third trench TR2_2 which at least partially extends into the substrate 100 may be formed in the cell region CR.

A fourth trench TR32_2 which at least partially extends into the substrate 100 may be formed in the second scribe region R32.

A width W2_2 of the third trench TR2_2 may be the same as a width W32_2 of the fourth trench TR32_2. A depth T2_2 of the third trench TR2_2 may be the same as a depth T32_2 of the fourth trench TR32_2.

In some example embodiments, the fourth trench TR32_2 formed in the second scribe region R32 may be formed in the same shape as the third trench TR2_2 formed in the cell region CR. Accordingly, it may be possible to improve defects caused by steps or sharp steps between the patterns formed in the cell region CR and the scribe region SLR in a later process.

After that, a first gate structure GS1 including a first gate insulating film GI1, a first gate electrode layer GE1, and a first gate capping layer GC1 may be formed inside the third trench TR2_2.

The first gate insulating film GI1 may extend along at least a partial profile of the third trench TR2_2. The first gate insulating film GI1 may include, for example, at least one of silicon oxide, silicon nitride, silicon oxynitride or a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

A first gate electrode layer GE1 may be formed on the first gate insulating film GI1. The first gate electrode layer GE1 may fill a part of the third trench TR2_2. The first gate electrode layer GE1 may include a conductive material. The first gate electrode layer GE1 may include, but not limited to, a metal, a metal nitride or polysilicon doped with impurities, and may be a single film or a composite film.

The first gate capping layer GC1 may extend along an upper face of the first gate electrode layer GE1. For example, the first gate capping layer GC1 may include an insulating material.

A second gate structure GS1 including a second gate insulating film GI2, a second gate electrode layer GE2, and a second gate capping layer GC2 may be formed inside the fourth trench TR32_2.

The second gate insulating film GI2 may extend along at least a partial profile of the fourth trench TR32_2. The second gate insulating film GI2 may include, for example, at least one of silicon oxide, silicon nitride, silicon oxynitride, and a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The second gate electrode layer GE2 may be formed on the second gate insulating film GI2. The second gate electrode layer GE2 may fill a part of the fourth trench TR32_2. The second gate electrode layer GE2 may include a conductive material. The second gate electrode layer GE2 may include, but not limited to, a metal, a metal nitride or polysilicon doped with an impurity, and may be a single film or a composite film.

The second gate capping layer GC2 may extend along an upper face of the second gate electrode layer GE2. For example, the second gate capping layer GC2 may include an insulating material such as but not limited to an oxide material and/or a nitride material.

The first gate structure GS1 and the second gate structure GS1 may be formed in the same process. Accordingly, the first gate insulating film GI1 and the second gate insulating film GI2 may include the same material, the first gate electrode layer GE1 and the second gate electrode layer GE2 may include the same material, and the first gate capping layer GC1 and the second gate capping layer GC2 may include the same material.

FIG. 21 is a schematic layout diagram of the region R3 according to some example embodiments, corresponding to FIG. 6. For convenience of explanation, the following description will focus on differences from those described using FIGS. 1 to 20.

From a planar view point, the direction DR2 in which the trench TR32_2 with the dummy word line DWL formed thereon extends may perpendicularly intersect the direction DR1 in which the trench TR2_2 with the word line (WL of FIG. 5) formed thereon extends. The dummy word line DWL may extend in a direction perpendicular to the word line (WL of FIG. 5).

Although some example embodiments have been described above with reference to the accompanying drawings, example embodiments are not limited to the above example embodiments, and may be fabricated in various different forms. Those of ordinary skill in the art will appreciate that inventive concepts may be embodied in other specific forms without changing the technical spirit or essential features of some example embodiments. Accordingly, the above-described example embodiments should be understood in all respects as illustrative and not restrictive. Further, example embodiments are not necessarily mutually exclusive with one another. For example, some example embodiments may include one or more features described with reference to one or more figures, and may also include one or more other features described with reference to one or more other figures.

What is claimed is:

1. A method for manufacturing a semiconductor device, the method comprising:
providing a substrate including a first region, and second and third regions around the first region, the second region between the first region and the third region;
sequentially forming a first mask layer and a first photoresist pattern on the substrate of the first to third regions;
etching the first mask layer by using the first photoresist pattern to form a mask pattern;
forming a spacer layer along a surface of the mask pattern;
forming a second mask layer on the spacer layer;
selectively forming a second photoresist pattern on the second mask layer of the second region; and
forming a first trench extending at least partially into the substrate of the first region and a second trench extending at least partially into the substrate of the third region, the forming the first and second trench by using the second photoresist pattern.

2. The method for manufacturing the semiconductor device of claim 1,
wherein a width of the mask pattern of the third region is same as a width of the mask pattern of the first region.

3. The method for manufacturing the semiconductor device of claim 1,
wherein a thickness of the mask pattern of the third region is same as a thickness of the mask pattern of the first region.

4. The method for manufacturing the semiconductor device of claim 1,
wherein an interval between mask patterns of the third region is same as an interval between mask patterns of the first region.

5. The method for manufacturing the semiconductor device of claim 1, further comprising:
etching the second mask layer of the first and third regions by using the second photoresist pattern to expose an upper face of the spacer layer and an upper face of the mask pattern of the first and third regions.

6. The method for manufacturing the semiconductor device of claim 1,
wherein a width of the second trench is same as a width of the first trench.

7. The method for manufacturing the semiconductor device of claim 1,
wherein a depth of the second trench is same as a depth of the first trench.

8. The method for manufacturing the semiconductor device of claim 1,
wherein a direction in which the second trench extends is parallel to a direction in which the first trench extends from a planar view point.

9. The method for manufacturing the semiconductor device of claim 1,
wherein a direction in which the second trench extends perpendicularly intersects a direction in which the first trench extends from a planar view point.

10. The method for manufacturing the semiconductor device of claim 1, further comprising:
forming a first gate insulating film on a side wall of and a bottom face of the first trench; and
forming a first gate electrode layer and a first gate capping layer on the first gate insulating film.

11. The method for manufacturing the semiconductor device of claim 1, further comprising:
forming a second gate insulating film on a side wall of and a bottom face of the second trench; and
forming a second gate electrode layer and a second gate capping layer on the second gate insulating film.

12. A method for manufacturing a semiconductor device, the method comprising:
providing a substrate including an element region, and first and second scribe regions around the element region, the first scribe region between the element region and the second scribe region;
sequentially forming a first mask layer and a first photoresist pattern on the substrate of the element region, the first scribe region, and the second scribe region;
etching the first mask layer by using the first photoresist pattern to form a mask pattern in the element region, the first scribe region, and the second scribe region;
forming a spacer layer along a surface of the mask pattern;
forming a second mask layer on the spacer layer;
selectively forming a second photoresist pattern on the second mask layer of the first scribe region;
forming a first alignment key by using the first photoresist pattern of the first scribe region;
forming a dummy key by using the first photoresist pattern of the second scribe region; and
forming a second alignment key by using the second photoresist pattern.

13. The method for manufacturing the semiconductor device of claim 12,
wherein a width of the dummy key is smaller than a width of the second alignment key from a planar view point.

14. The method for manufacturing the semiconductor device of claim 12,
wherein a width of the dummy key is same as a width of the first alignment key from a planar view point.

15. The method for manufacturing the semiconductor device of claim 12,
wherein an interval between dummy keys is same as an interval between first alignment keys from a planar view point.

16. The method for manufacturing the semiconductor device of claim 12, further comprising:
simultaneously forming a first trench extending at least partially into the substrate of the element region, and a second trench extending at least partially into the substrate of the second scribe region.

17. The method for manufacturing the semiconductor device of claim 12,
wherein the second photoresist pattern is not formed in the element region and the second scribe region.

18. A method for manufacturing a semiconductor device, the method comprising:
providing a substrate including an element region, and first and second scribe regions around the element region, the first scribe region between the element region and the second scribe region;
sequentially forming a first oxide layer, a second oxide layer, and a first mask layer on the element region, the first scribe region and the second scribe region;
sequentially forming a second mask layer and a first photoresist pattern on the first mask layer;
etching the second mask layer by using the first photoresist pattern to form a mask pattern;
forming a spacer layer along an upper face of the first mask layer and a surface of the mask pattern;
forming a third mask layer on the spacer layer;
selectively forming a second photoresist pattern on the third mask layer of the first scribe region;
etching the second mask layer of the element region and the second scribe region by using the second photoresist pattern to expose an upper face of the spacer layer of the element region and the second scribe region and an upper face of the mask pattern; and
forming a first trench at least partially extending into the substrate in the element region, and a second trench at least partially extending into the substrate in the second scribe region, by utilizing etching selectivity of the spacer layer and the mask pattern,
wherein a width of the first trench is same as a width of the second trench, and
a depth of the first trench is same as a depth of the second trench.

19. The method for manufacturing the semiconductor device of claim 18, further comprising:
removing the spacer layer, the mask pattern, the first mask layer, the second oxide layer, and the first oxide layer of the element region, the first scribe region, and the second scribe region; and
removing the third mask layer and the second photoresist pattern of the first scribe region.

20. The method for manufacturing the semiconductor device of claim 18, further comprising:
forming a first gate insulating film, a first gate electrode layer, and a first gate capping layer inside the first trench; and
forming a second gate insulating film, a second gate electrode layer, and a second gate capping layer inside the second trench.
